(19) United States
(12) Patent Application Publication
(10) Pub. No.: US 2012/0235843 A1
(43) Pub. Date: Sep. 20, 2012

(54) DIGITAL-TO-ANALOG CONVERTER AND CIRCUIT

(75) Inventor: Fumihiko KATO, Kanagawa (JP)

(73) Assignee: Renesas Electronics Corporation, Kanagawa (JP)

(21) Appl. No.: 13/420,477

(22) Filed: Mar. 14, 2012

(30) Foreign Application Priority Data
Mar. 18, 2011 (JP) 2011-060954

(51) Int. Cl. H03M 1/66

(52) U.S. Cl. 341/144

(57) ABSTRACT

The selection circuit is supplied with a low-voltage-side power supply voltage from a low-voltage-side power supply, and outputs a voltage that changes in 2^{m} (m is an integer equal to or greater than 2) levels according to m-bit digital data to be input. The level shift circuit generates a voltage by shifting a level of the voltage output from the selection circuit by a predetermined value. The n (n is an integer equal to or greater than 2)-bit digital-to-analog converter is supplied with a high-voltage-side power supply voltage from a high-voltage-side power supply, and outputs an output voltage that changes in 2^{(m+n)} levels by changing the voltage generated by the level shift circuit in 2ⁿ levels according to n (n is an integer equal to or greater than 2)-bit digital data to be input.

### CROSS-REFERENCE TO RELATED APPLICATIONS

This application is based upon and claims the benefit of priority from Japanese patent application No. 2011-060954, filed on Mar. 18, 2011, the disclosure of which is incorporated herein in its entirety by reference.

### BACKGROUND

The present invention relates to a digital-to-analog converter and circuit, and more particularly, to a digital-to-analog converter of a bit division type and circuit.

In recent years, so-called optical discs, such as a CD (Compact Disc CD-ROM (Compact Disc-Read Only Memory), a CD-R (Compact Disc-Recordable), and a CD-RW (Compact Disc-ReWritable), are widely used as data recording media. Data recording or reproduction using such optical discs is carried out by an optical recording/reproducing apparatus. The optical recording/reproducing apparatus follows a spiral track by tracking servo, and maintains a distance between an objective lens and a recording surface of an optical disc constant by focusing servo. This enables normal recording of data onto the optical disc, or normal reproduction of data from the optical disc.

The servo processing described above is carried out based on an error signal which is generated based on a distribution of reflected light of a laser beam applied to the optical disc. Specifically, a tracking servo signal and a focus servo signal are generated by performing an appropriate internal digital operation on the error signal. The tracking servo signal and the focusing servo signal are converted into analog signals by a digital-to-analog converter. The converted signals are respectively input to a tracking actuator (tracking coil) and a focusing actuator (focusing coil), which are provided in an optical pickup, through an actuator driver. This allows the tracking actuator (tracking coil) and the focusing actuator (focusing coil) to be driven.

The above-mentioned servo processing is carried out by a semiconductor device, such as a system LSI, which is mounted on the optical recording/reproducing apparatus. In other words, in the semiconductor device mounted on the optical recording/reproducing apparatus, the digital-to-analog converter is an essential electronic circuit. For this reason, there is a demand for implementation of a technique for area saving in the digital-to-analog converter in order to satisfy the recent demand for a reduction in cost of LSIs.

To satisfy such a demand, a digital-to-analog converter that achieves area saving by reducing the number of elements is proposed (Japanese Unexamined Patent Application Publication No. 2006-270858). FIG. 15 is a circuit diagram showing a configuration of a digital-to-analog converter 600 that achieves area saving by reducing the number of elements. The digital-to-analog converter 600 includes a reference voltage generating circuit 601, a switch group 602, a logic circuit 603, and an operational amplifier 605. The reference voltage generating circuit 601 generates 2^{K} reference voltages (V(1), V(2), . . . , V(2^{K})). The logic circuit 603 receives 2^{K}-bit input digital data (B(2^{K}), B(2^{K-1}), . . . , B3, B2, B1) and outputs logical operation values. The switch group 602 selects two identical or different reference voltages from among the 2^{K} reference voltages based on the logical operation value, and outputs the selected reference voltages to terminals T1 and T2. The operational amplifier 605 amplifies and outputs a voltage generated by internally dividing (interpolating) or externally dividing (extrapolating) between a voltage V (T1) at the terminal T1 and a voltage V (T2) at the terminal T2 at a ratio of 1:2.

The reference voltage generating circuit 601 includes a resistor string formed of a plurality of resistors. In the reference voltage generating circuit 601, the resistor string connected between a terminal for supplying a voltage VA and a terminal for supplying a voltage VB outputs the 2^{K} reference voltages. The 2^{K} reference voltages are extracted and output from taps at nodes between the resistors of the resistor string.

The logic circuit 603 includes a first logic circuit 631 and a second logic circuit 632. The first logic circuit 631 outputs logical operation values of odd-numbered bit signals (B(2^{K-1}), . . . , B3, B1) in the 2^{K}-bit input digital data in which the bits from the lowest-order bit B1 to the highest-order bit B(2^{K}) are ordered. The second logic circuit 632 outputs logical operation values of even-numbered bit signals (B(2^{K}), . . . , B4, B2).

The switch group 602 constituting a selection circuit includes a first switch group 621 and a second switch group 622. The first switch group 621 is connected between each voltage supply terminal for outputting the 2^{K} reference voltages and the terminal T2, and is controlled based on an output value of the first logic circuit 631. The second switch group 622 is connected between each voltage supply terminal for outputting the 2^{K} reference voltages and the terminal T1, and is controlled based on an output value of the second logic circuit 632.

The operational amplifier 605 includes switches SW61 to SW63, capacitors C11 and C12, and a differential amplifier 651. A first end of the switch SW61 is connected to the terminal T1. The capacitor C11 is connected between a second end of the switch SW61 and a reference voltage Vr65. A first end of the switch SW62 is connected to the terminal T2. The capacitor C12 is connected between a second end of the switch SW62 and the reference voltage Vr65. The switch SW63 is connected between the second end of the switch SW61 and the second end of the switch SW62. A node between the switches SW61 and SW63 and the capacitor C11 is connected to a non-inverting input terminal (+) of the differential amplifier 651. The differential amplifier 651 has a voltage follower configuration with an output terminal connected to an inverting input terminal (−). The differential amplifier 651 outputs an output voltage Vout.

Upon receiving the 2^{K}-bit input digital data (B(2^{K}), B(2^{K-1}), . . . , B3, B2, B1), the digital-to-analog converter 600 can select and output 4^{K} voltage levels at maximum depending on a data signal.

In the digital-to-analog converter 600, the number of reference voltages to be generated by the reference voltage generating circuit 601 can be reduced to 2^{K} at minimum by using the operational amplifier 605 capable of amplifying and outputting the voltage generated by internally dividing or externally dividing between the voltages at the terminals T1 and T2 at the ratio of 1:2. Thus, the number of reference voltages is extremely small even in the case where the number of bits increases. Therefore, an increase in the number of elements constituting the switch group 602 and the logic circuit 603, which select reference voltages, can be suppressed, and thus a digital-to-analog converter that achieves area saving can be implemented.

In addition, there are proposed a digital-to-analog converter capable of downsizing and reducing power consumption of a semiconductor integrated circuit for an analog-to-digital conversion system (Japanese Unexamined Patent Application Publication No. 2009-65718) and a digital-to-analog converter that divides input digital data into high-order bits and low-order bits to thereby perform digital-to-analog conversion (Japanese Unexamined Patent Application Publication No. 2008-85711).

### SUMMARY

However, the present inventor has found that the digital-to-analog converters described above have problems as described below. In order to satisfy the recent demand for a reduction in cost of LSIs, a more area saving than that is achieved in the digital-to-analog converters described above is required. Thus, the area saving effect obtained by the digital-to-analog converters described above is insufficient, and it is necessary to establish a technique for achieving further area saving. The reasons for this are described below.

For example, a voltage applied to a logic area in a system LSI mounted on an optical recording/reproducing apparatus is about 1.0 V to 1.5 V. For this reason, a low-breakdown-voltage transistor having a thin gate oxide film and a small channel can be used as each transistor constituting the logic area. Meanwhile, a digital-to-analog output signal for servo driving, which is output from an optical pickup LSI, requires a range of about 3 V. Accordingly, it is necessary for each transistor constituting the digital-to-analog converter for the optical pickup to ensure a sufficient breakdown voltage for the applied voltage of 3 V. This necessitates the use of a high-breakdown-voltage transistor having a thick gate oxide film and a large channel in the digital-to-analog converter for the optical pickup.

Because a power supply voltage of 3.0 V is used in the above-mentioned digital-to-analog converters, the whole circuit of the digital-to-analog converters should be designed using high-breakdown-voltage transistors. Further, it is necessary to shift the level of each digital data signal and control signal from the logic area to 3.0 V. Accordingly, it is necessary to provide digital level shift circuits corresponding to the number of digital data signals and control signals from the logic area. Furthermore, when the operational amplifier 605 incorporating the capacitors C11 and C12 is disposed at the subsequent stage of the switches SW61 and SW62, charging and discharging of the capacitors C11 and C12 need to be performed at high speed to achieve high-speed digital-to-analog conversion. Therefore, in terms of time constant, there is a need to reduce the resistance between the amplification capacitor C11 and the reference voltage generating circuit 601 and the resistance between the amplification capacitor C12 and the reference voltage generating circuit 601. As a result, it is necessary to use transistors having a sufficiently large channel width as the transistors constituting the switch group 602 and the switches SW61 to SW63, in order to reduce on-resistance.

In short, in the digital-to-analog converters described above, it is necessary not only to use high-breakdown-voltage transistors, but also to provide a number of digital level shift circuits and to use transistors with large dimensions as switches. This results in being unable to achieve further area saving in the digital-to-analog converters.

An aspect of the present invention is a digital-to-analog converter including: a selection circuit that is supplied with a low-voltage-side power supply voltage from a low-voltage-side power supply, and outputs a voltage that changes in 2^{m} (m is an integer equal to or greater than 2) levels depending on m-bit digital data to be input; a level shift circuit that generates a voltage by shifting a level of the voltage output from the selection circuit by a predetermined value; and an n (n is an integer equal to or greater than 2)-bit digital-to-analog converter that is supplied with a high-voltage-side power supply voltage from a high-voltage-side power supply, and outputs an output voltage that changes in 2^{(m+n)} levels by changing the voltage generated by the level shift circuit in 2ⁿ levels depending on n-bit digital data to be input. In the digital-to-analog converter according to an aspect of the present invention, a low-breakdown-voltage transistor can be used as the selection circuit. Generally, the area of a low-breakdown-voltage transistor is smaller than that of a high-breakdown-voltage transistor. Consequently, the area of the selection circuit can be saved, thereby enabling area saving in the digital-to-analog converter.

According to an aspect of the present invention, it is possible to provide a digital-to-analog converter and circuit capable of achieving further area saving.

### BRIEF DESCRIPTION OF THE DRAWINGS

The above and other aspects, advantages and features will be more apparent from the following description of certain embodiments taken in conjunction with the accompanying drawings, in which:

FIG. 1 is a circuit diagram showing a configuration of a digital-to-analog converter 100 according to a first embodiment;

FIG. 2 is a circuit diagram showing a configuration of a selection circuit 21 according to the first embodiment;

FIG. 3 is a circuit diagram showing a configuration of a low-order digital-to-analog converter 6 according to the first embodiment;

FIG. 4 is a graph showing relationships among input digital data D[5:0], an output voltage Vnh, and an output voltage Vout according to the first embodiment;

FIG. 5 is a circuit diagram showing a configuration of a digital-to-analog converter 200 according to a second embodiment;

FIG. 6 is a circuit diagram showing a configuration of a selection circuit 22 according to the second embodiment;

FIG. 7 is an operation chart showing operations in accordance with high-order bits D[5:3] of the selection circuit 22 and a bit dividing unit 82 according to the second embodiment;

FIG. 8 is a circuit diagram showing a configuration of a digital-to-analog converter 300 according to a third embodiment;

FIG. 9 is a circuit diagram showing a configuration of a selection circuit 23 according to the third embodiment;

FIG. 10 is an operation chart showing operations in accordance with the high-order bits D[5:3] of the selection circuit 23 and a bit dividing unit 83 according to the third embodiment;

FIG. 11 is a circuit diagram showing a configuration of a digital-to-analog converter 400 according to a fourth embodiment;

FIG. 12 is a circuit diagram showing a configuration of a selection circuit 24 according to the fourth embodiment;

FIG. 13 is a circuit diagram showing a configuration of a digital-to-analog converter 500 according to a fifth embodiment;

FIG. 14 is a graph showing relationships among input digital data D[5:0], an output voltage Vnh, and an output voltage Vout according to the fifth embodiment; and

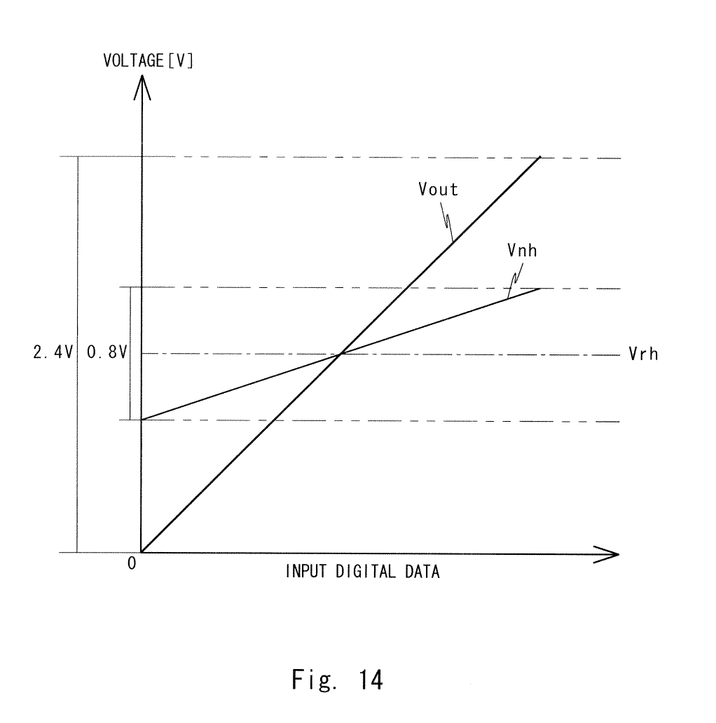

FIG. 15 is a circuit diagram showing a configuration of a digital-to-analog converter 600 in which the number of elements is reduced to thereby achieve area saving.

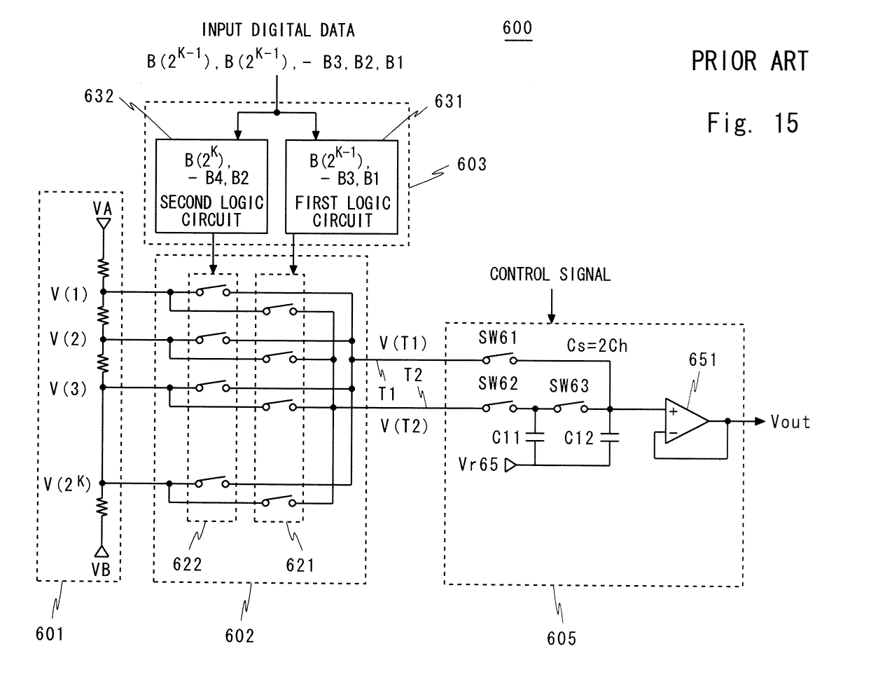

### DETAILED DESCRIPTION

Hereinafter, embodiments of the present invention will be described with reference to the accompanying drawings. The same elements are denoted by the same reference numerals throughout the drawings, and repeated description thereof is omitted as necessary.

### First Embodiment

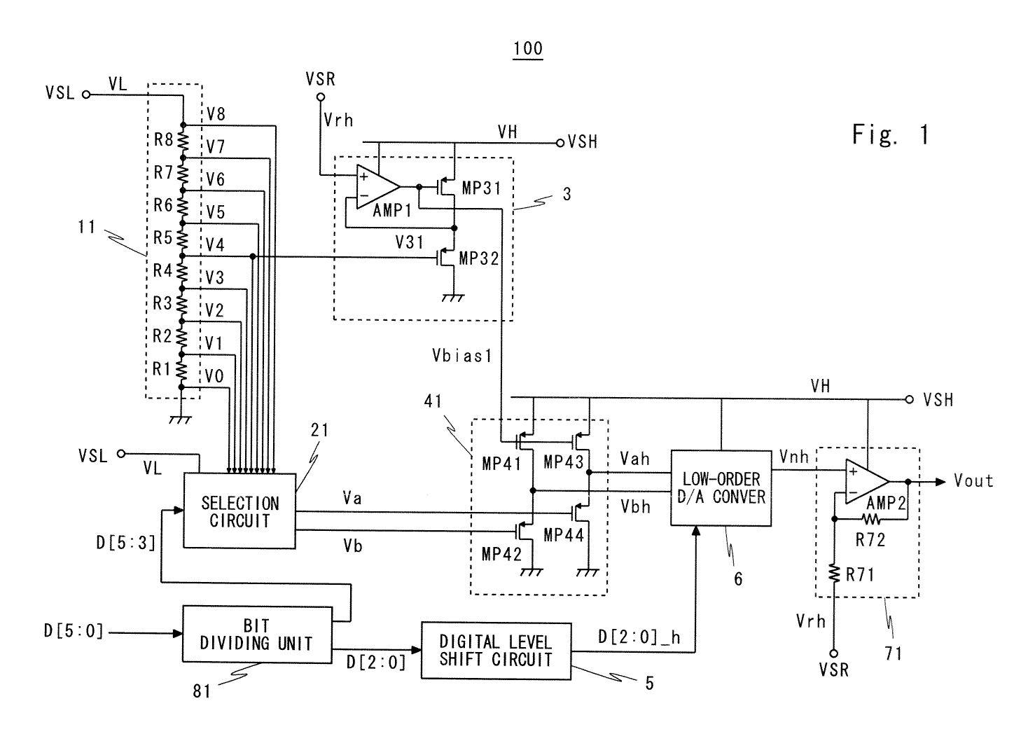

First, a digital-to-analog converter 100 according to a first embodiment of the present invention will be described. The digital-to-analog converter 100 is a 6-bit digital-to-analog converter. FIG. 1 is a circuit diagram showing the configuration of the digital-to-analog converter 100 according to the first embodiment. The digital-to-analog converter 100 includes a voltage dividing circuit 11, a selection circuit 21, a bias generation circuit 3, an analog level shift circuit 41, a digital level shift circuit 5, a low-order digital-to-analog converter 6, an output amplifier circuit 71, and a bit dividing unit 81.

The bit dividing unit 81 receives 6-bit input digital data D[5:0]. The bit dividing unit 81 divides the input digital data D[5:0] into three high-order bits D[5:3] and three low-order bits D[2:0]. The high-order bits D[5:3] are output to the selection circuit 21, and the low-order bits D[2:0] are output to the digital level shift circuit 5.

The voltage dividing circuit 11 includes resistors R1 to R8 that are connected in series from a ground GND to a low-voltage-side power supply VSL. In this embodiment, the resistors R1 to R8 have the same resistance value. The low-voltage-side power supply VSL applies a low-voltage-side power supply voltage VL to the resistor R8. Voltages V1 to V8 are respectively output from high-voltage-side ends of the resistors R1 to R8 to the selection circuit 21. A voltage V0, which is a ground voltage, is output from a low-voltage-side end of the resistor R1 to the selection circuit 21.

The selection circuit 21 receives the high-order bits D[5:3]. The selection circuit 21 decodes the high-order bits D[5:3] and selects two adjacent voltages from among the voltages V0 to V8 depending on the generated decoded value. In other words, the selection circuit 21 selects a voltage Vk and a voltage V (k+1) depending on a decoded value k (k is an integer from 0 to 7). Then, the selection circuit 21 outputs the voltage Vk, which is a lower voltage, to the analog level shift circuit 41 as a voltage Va, and outputs the voltage V (k+1), which is a higher voltage, to the analog level shift circuit 41 as a voltage Vb. When the decoded value is “1”, for example, the selection circuit 21 selects the voltages V1 and V2. Then, the selection circuit 21 outputs the voltage V1 as the voltage Va and outputs the voltage V2 as the voltage Vb.

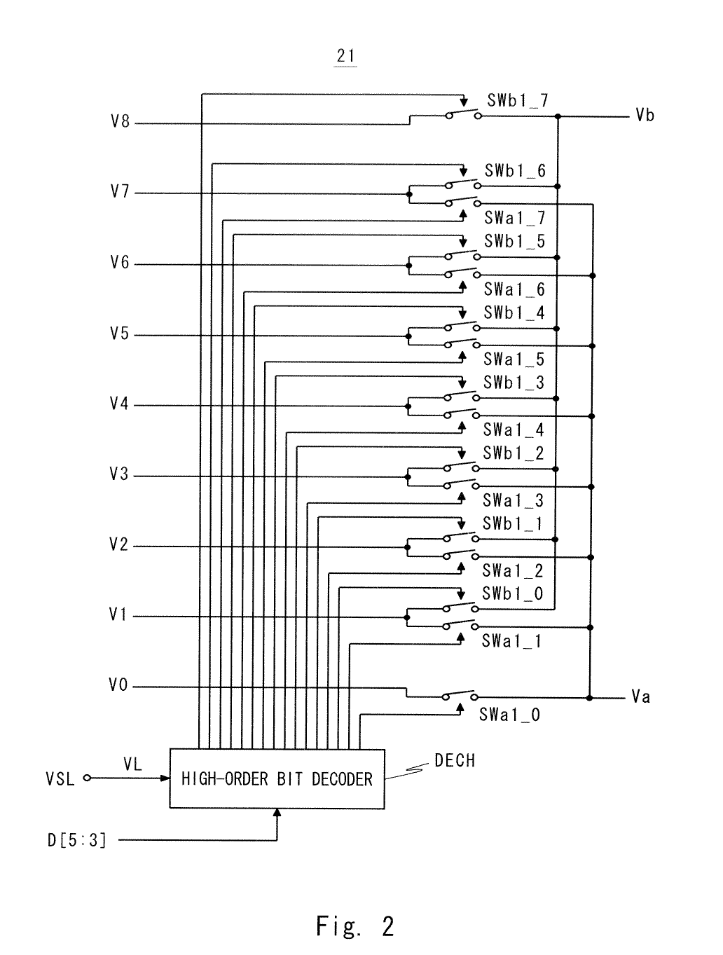

The configuration of the selection circuit 21 will now be described. FIG. 2 is a circuit diagram showing the configuration of the selection circuit 21. The selection circuit 21 includes switches SWa1_0 to SWa1_7 and SWb1_0 to SWb1_7 and a high-order bit decoder DECH. The switches SWa1_0 to SWa1_7 and SWb1_0 to SWb1_7 are each composed of a transistor. Respective one ends of the switches SWa1_0 to SWa1_7 are supplied with the voltages V0 to V7 from the voltage dividing circuit 11. The respective other ends of the switches SWa1_0 to SWa1_7 are connected to an output node of the voltage Va. Respective one ends of the switches SWb1_0 to SWb1_7 are supplied with the voltages V1 to V8 from the voltage dividing circuit 11. The respective other ends of the switches SWb1_0 to SWb1_7 are connected to an output node of the voltage Vb.

The high-order bit decoder DECH is supplied with the low-voltage-side power supply voltage VL. The high-order bit decoder DECH decodes the high-order bits D[5:3] and controls turning on/off of each of the switches SWa1_0 to SWa1_7 and SWb1_0 to SWb1_7 depending on the decoded value.

In the selection circuit 21, the switches SWa1_0 to SWa1_7 and SWb1_0 to SWb1_7 are supplied with signals having a voltage level equal to or less than the low-voltage-side power supply voltage VL from the high-order bit decoder DECH. The voltages V0 to V8 are voltages obtained by dividing the low-voltage-side power supply voltage VL, and thus the voltages V0 to V8 are equal to or less than the low-voltage-side power supply voltage VL. Accordingly, in the selection circuit 21, low-breakdown-voltage transistors can be used as the switches SWa1_0 to SWa1_7 and SWb1_0 to SWb1_7.

Returning to FIG. 1, the configuration of the digital-to-analog converter 100 will further be described. The bias generation circuit 3 includes an amplifier AMP1 and Pch transistors MP31 and MP32. The Pch transistors MP31 and MP32 are cascode-connected between a high-voltage-side power supply VSH and the ground GND. Specifically, the source of the Pch transistor MP31 is supplied with a high-voltage-side power supply voltage VH from the high-voltage-side power supply VSH. The drain of the Pch transistor MP31 is connected to the source of the Pch transistor MP32. The drain of the Pch transistor MP32 is connected to the ground GND. The gate of the Pch transistor MP32 is supplied with the voltage V4 from the voltage dividing circuit 11. A non-inverting input terminal of the amplifier AMP1 is supplied with a high-voltage-side reference voltage Vrh from a high-voltage-side reference power supply VSR. An inverting input terminal of the amplifier AMP1 is connected to each of the drain of the Pch transistor MP31 and the source of the Pch transistor MP32. An output terminal of the amplifier AMP1 is connected to each of the gate of the Pch transistor MP31 and the analog level shift circuit 41.

The analog level shift circuit 41 is a circuit that shifts the voltage level of each of the voltages Va and Vb, which are supplied from the selection circuit 21, to the high voltage side. The analog level shift circuit 41 outputs voltages Vah and Vbh, which are respectively obtained by shifting the voltage levels of the voltages Va and Vb, to the low-order digital-to-analog converter 6. The analog level shift circuit 41 includes Pch transistors MP41 to MP44. The Pch transistors MP41 and MP43 have the same channel width and the same channel length as those of the Pch transistor MP31. The Pch transistors MP42 and MP44 have the same channel width and the same channel length as those of the Pch transistor MP32.

The Pch transistors MP41 and MP42 are cascode-connected between the high-voltage-side power supply VSH and the ground GND. Specifically, the source of the Pch transistor MP41 is supplied with the high-voltage-side power supply voltage VH from the high-voltage-side power supply VSH. The drain of the Pch transistor MP41 is connected to the source of the Pch transistor MP42. The drain of the Pch transistor MP42 is connected to the ground GND. The gate of the Pch transistor MP41 is supplied with a bias voltage Vbias1 from the output terminal of the amplifier AMP1 of the bias generation circuit 3. The gate of the Pch transistor MP42 is supplied with the voltage Vb from the selection circuit 21. The voltage Vbh is output from a node between the Pch transistors MP41 and MP42 to the low-order digital-to-analog converter 6.

The Pch transistors MP43 and MP44 are cascode-connected between the high-voltage-side power supply VSH and the ground GND. Specifically, the source of the Pch transistor MP43 is supplied with the high-voltage-side power supply voltage VH from the high-voltage-side power supply VSH. The drain of the Pch transistor MP43 is connected to the source of the Pch transistor MP44. The drain of the Pch transistor MP44 is connected to the ground GND. The gate of the Pch transistor MP43 is supplied with the bias voltage Vbias1 from the output terminal of the amplifier AMP1 of the bias generation circuit 3. The gate of the Pch transistor MP44 is supplied with the voltage Va from the selection circuit 21. The voltage Vah is output from a node between the Pch transistors MP43 and MP44 to the low-order digital-to-analog converter 6.

The digital level shift circuit 5 receives the low-order bits D[2:0]. The digital level shift circuit 5 is a circuit that shifts the voltage level of the low-order bits D[2:0] to the high voltage side. The digital level shift circuit 5 outputs high-voltage low-order bits D[2:0]_h, which are obtained by shifting the voltage level of the low-order bits D[2:0], to the low-order digital-to-analog converter 6.

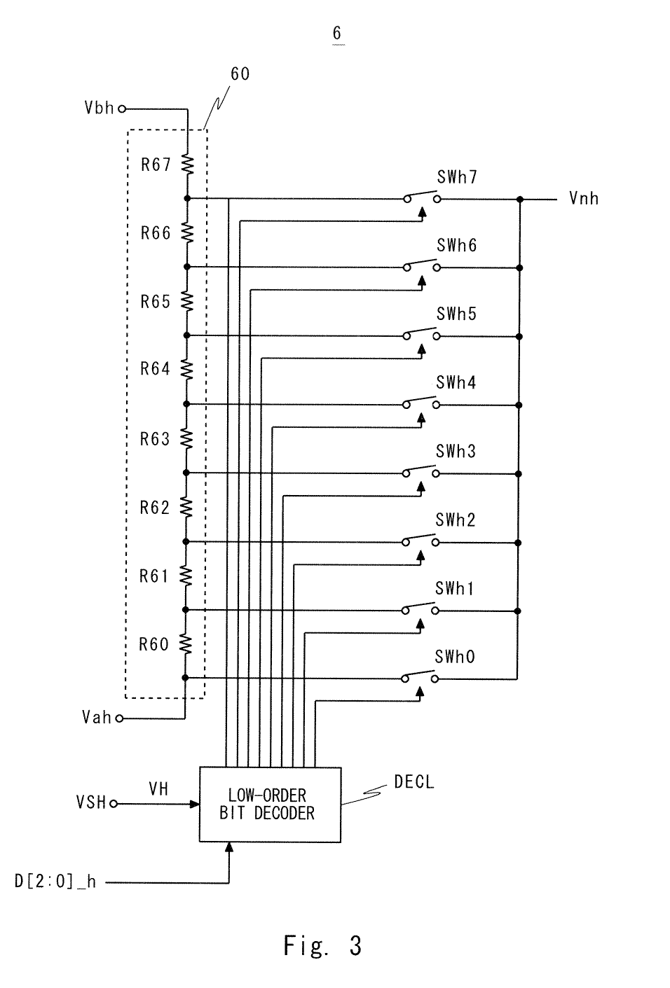

The low-order digital-to-analog converter 6 is supplied with power from a high-voltage-side power supply VRH, and generates an output voltage Vnh based on the voltages Vah and Vbh and the high-voltage low-order bits D[2:0]_h. The configuration of the low-order digital-to-analog converter 6 will now be described. FIG. 3 is a circuit diagram showing the configuration of the low-order digital-to-analog converter 6. The low-order digital-to-analog converter 6 includes a voltage dividing circuit 60, high-voltage transistor switches SWh0 to SWh7, and a low-order bit decoder DECL.

The voltage dividing circuit 60 includes resistors R60 to R67. The resistors R60 to R67 are connected in series in this order from the voltage Vah toward the voltage Vbh. Voltages V60 to V67 are respectively output to the high-voltage transistor switches SWh0 to SWh7 from the low-voltage-side ends of the resistors R60 to R67. The low-order bit decoder DECL decodes the high-voltage low-order bits D[2:0]_h, and turns on only a high-voltage transistor switch SWhk when the decoded value is “k”.

In the low-order digital-to-analog converter 6, the high-voltage transistor switches SWh0 to SWh7 are supplied with signals having a voltage level equal to or less than the high-voltage-side power supply voltage VH from the low-order bit decoder DECL. The voltages V0 to V8 are voltages obtained by shifting the voltage levels to the high voltage side by the analog level shift circuit 41. Accordingly, in the low-order digital-to-analog converter 6, high-breakdown-voltage transistors are used as the high-voltage transistor switches SWh0 to SWh7.

Returning to FIG. 1, the configuration of the digital-to-analog converter 100 will further be described. The output amplifier circuit 71 is supplied with power from the high-voltage-side power supply VSH, and outputs an output voltage Vout obtained by amplifying the output voltage Vnh. The output amplifier circuit 71 includes an amplifier AMP2 and resistors R71 and R72. The amplifier AMP2 is supplied with power from the high-voltage-side power supply VSH. A non-inverting input terminal of the amplifier AMP2 is supplied with the output voltage Vnh from the low-order digital-to-analog converter 6. An inverting input terminal of the amplifier AMP2 is supplied with the high-voltage-side reference voltage Vrh from the high-voltage-side reference power supply VSR through the resistor R71. The inverting input terminal of the amplifier AMP2 is connected to the output terminal of the amplifier AMP2 through the resistor R72. The output terminal of the amplifier AMP2 outputs the output voltage Vout.

That is, the output amplifier circuit 71 is configured as a positive-phase amplifier. Assuming that the resistance value of the resistor R71 is represented by “R” and the resistance value of the resistor R72 is represented by “NR” (N is an arbitrary positive real number), an amplification factor Av of the output amplifier circuit 71 can be expressed by the following equation (1).

Av=1+N (1)

Subsequently, the operation of the digital-to-analog converter 100 will be described. The following description will be made assuming that the low-voltage-side power supply voltage VL is 1.0 V; the high-voltage-side power supply voltage VH is 3.0 V; and the high-voltage-side reference voltage Vrh is 1.5V which is a half of the high-voltage-side power supply voltage VH. The voltage dividing circuit 11 generates the voltages V0 to V8 by dividing the low-voltage-side power supply voltage VL of 1.0 V into eight voltage levels.

In the bias generation circuit 3, the voltage V4 (0.5 V), which is an intermediate voltage between the voltages V0 to V8, is supplied to the gate of the Pch transistor MP32. Accordingly, since the high-voltage-side reference voltage Vrh is 1.5 V, the amplifier AMP1 applies a feedback so that a voltage V31 at a node between the Pch transistor MP31 and the Pch transistor MP32 is maintained at 1.5 V when the voltage V4 (0.5 V) is supplied to the gate of the Pch transistor MP32. That is, the bias generation circuit 3 outputs the bias voltage Vbias1 to cause a bias current for generating the output voltage (voltage. V31), which is obtained by shifting the level of the input voltage (voltage V4) by 1.0 V, to flow.

The high-order hit decoder DECH of the selection circuit 21 decodes the high-order bits D[5:3]. Then, the high-order hit decoder DECH turns on switches SWa1_k (k is an integer from 0 to 8) and SWb1_k according to the decoding result. For example, when a switch SWa1_1 turns on, a switch SWB1_1 also turns on. In this case, the selection circuit 21 outputs the voltage V1 as the voltage Va and outputs the voltage V2 as the voltage Vb. That is, the selection circuit 21 outputs, as the voltage Va, the lower voltage of adjacent voltages among the voltages V0 to V8, and outputs, as the voltage Vb, the higher voltage of the adjacent voltages. Accordingly, there are eight combinations of the voltages Vb and Va, i.e., the voltages V0 and V1; the voltages V1 and V2; the voltages V2 and V3; the voltages V3 and V4; the voltages V4 and V5; the voltages V5 and V6; the voltages V6 and V7; and the voltages V7 and V8.

The gates of the Pch transistors MP41 and MP43 of the analog level shift circuit 41 are supplied with the bias voltage Vbias1 from the bias generation circuit 3. Accordingly, the analog level shift circuit 41 outputs the voltages Vah and Vbh which are respectively obtained by shifting, by 1.0 V, the levels of the voltages Va and Vb respectively supplied to the gates of the Pch transistors MP42 and MP44.

The low-order bit decoder DECL of the low-order digital-to-analog converter 6 decodes the high-voltage low-order bits D[2:0]_h, and turns on only one of the high-voltage transistor switches SWh0 to SWh7 according to the decoding result. As a result, the low-order digital-to-analog converter 6 outputs, as the output voltage Vnh, one of the eight voltages obtained by dividing the voltage between the voltage Vah and voltage Vbh. As described above, there are eight combinations of the voltages Vah and Vbh to be output from the analog level shift circuit 41. Thus, the output voltage Vnh is output as a voltage that changes in 64 (=2⁶) levels in response to a 6-bit input signal. The output voltage Vnh is a voltage in the range of 1.5 V±0.5 V.

The output amplifier circuit 71 amplifies the output voltage Vnh with the amplification factor expressed in the equation (1), and outputs the output voltage Vout. The above-mentioned operation allows the digital-to-analog converter 100 to convert the 6-bit input digital data D[5:0], which is a digital signal, into the output voltage Vout which is an analog signal. The output amplifier circuit 71 adjusts the resistance ratio between the resistors R71 and R72, thereby making it possible to adjust the dynamic range of the output voltage Vout with the high-voltage-side reference voltage Vrh as a center.

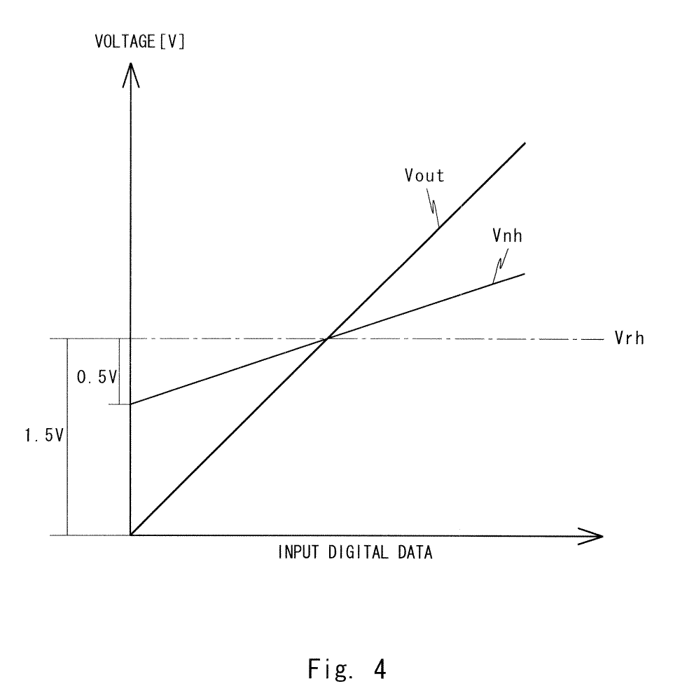

For example, assuming that the ratio between the resistance values of the resistors R71 and R72 is 1:2, the output amplifier circuit 71 has a triple amplification factor. In this case, the output voltage Vout is a voltage in the range of 1.5 V±1.5 V, i.e., a voltage in the range of 0 V to 3.0 V. FIG. 4 is a graph showing relationships among the input digital data D[5:0], the output voltage Vnh, and the output voltage Vout. As seen from FIG. 4, the digital-to-analog converter 100 can obtain the output voltage Vout in the range of the high-voltage-side reference voltage Vrh±1.5 V depending on the input digital data D[5:0]. Note that the output voltage Vnh and the output voltage Vout change stepwise depending on the input digital data D[5:0]. FIG. 4 illustrates changes of the output voltage Vnh and the output voltage Vout as straight lines, for simplification of the drawing.

In the digital-to-analog converter 100, the selection circuit 21 includes a plurality of switches. As described above, however, low-breakdown-voltage transistors can be used as the switches of the selection circuit 21. Generally, low-breakdown-voltage transistors are smaller than high-breakdown-voltage transistors. For example, the area of each low breakdown voltage (about 1 V) transistor for use in the selection circuit 21 is about one tenth of the area of each high breakdown voltage (about 3V) transistor for use in the low-order digital-to-analog converter.

The gates of the Pch transistors MP42 and MP44 of the analog level shift circuit 41 respectively receive the voltages Va and Vb output through the low-breakdown-voltage transistors serving as the switches of the selection circuit 21. Accordingly, a current flowing through each switch of the selection circuit 21 is small, so there is no need to reduce on-resistances of the Pch transistors each serving as a switch. As a result, the area of each low-breakdown-voltage transistor for use in the selection circuit 21 can be further reduced.

Therefore, even when multiple switches each composed of a low-breakdown-voltage transistor are provided, the area of the selection circuit 21 can be sufficiently reduced. Consequently, according to this configuration, it is possible to provide the digital-to-analog converter 100 capable of achieving area saving.

As described above, the selection circuit 21 operates at a voltage equal to or less than the low-voltage-side power supply voltage VL. Accordingly, the bit dividing unit 81 can supply the high-order bits D[5:3], which are obtained by dividing the input digital data D[5:0] of 1.0 V from a logic area driven at the low-voltage-side power supply voltage VL, directly to the selection circuit 21. This eliminates the need for shifting the level of the high-order bits D[5:3], unlike the low-order bits D[2:0]. Therefore, there is no need to provide a level shift circuit for high-order bits. As a result, the digital-to-analog converter 100 is more advantageous in terms of area saving.

### Second Embodiment

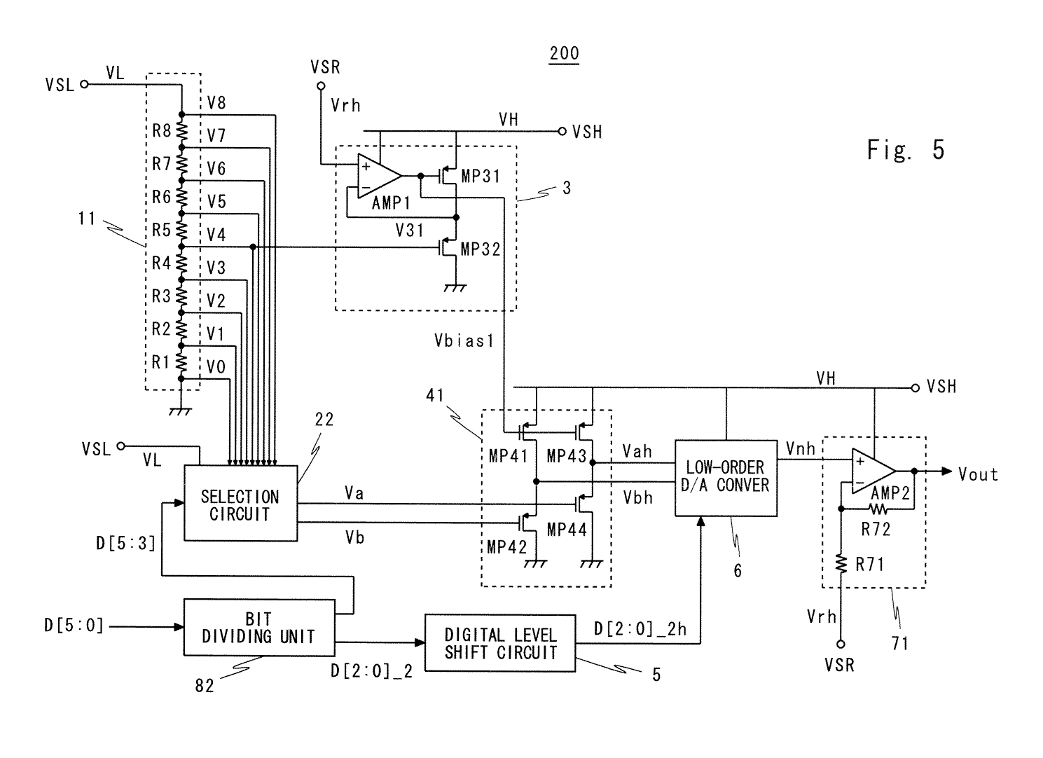

Next, a digital-to-analog converter 200 according to a second embodiment of the present invention will be described. FIG. 5 is a circuit diagram showing the configuration of the digital-to-analog converter 200 according to the second embodiment. The digital-to-analog converter 200 has a configuration in which the selection circuit 21 of the digital-to-analog converter 100 is replaced by a selection circuit 22 and the bit dividing unit 81 is replaced by a bit dividing unit 82.

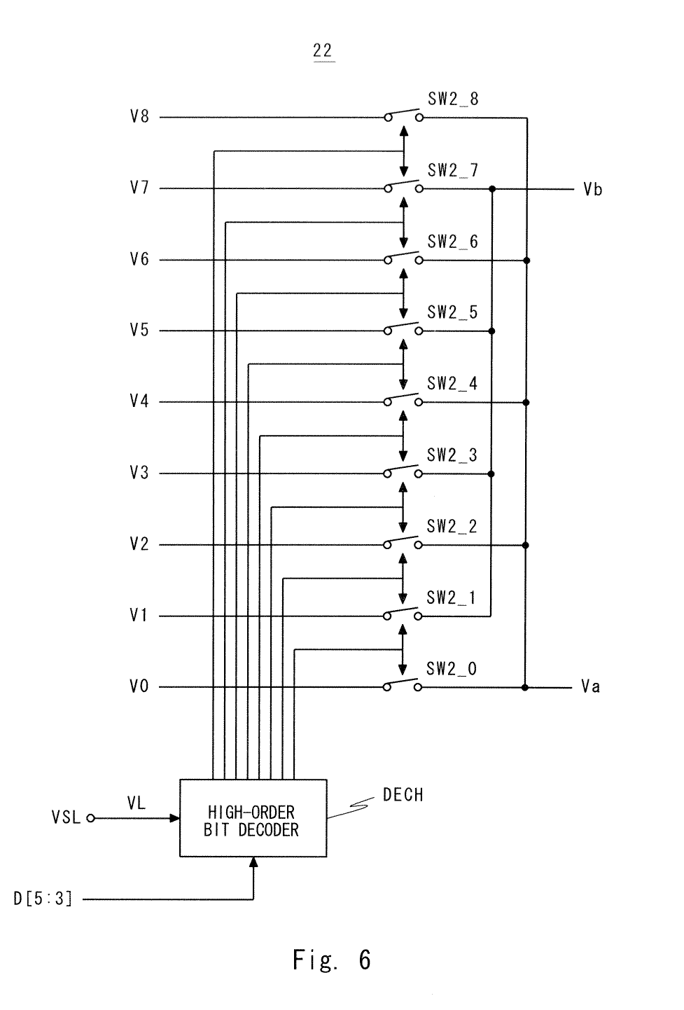

The selection circuit 22 will be described. FIG. 6 is a circuit diagram showing the configuration of the selection circuit 22. The selection circuit 22 includes switches SW2_0 to SW2_8 and the high-order bit decoder DECH. The switches SW2_0 to SW2_8 are each composed of a low-breakdown-voltage transistor, as in the selection circuit 21 according to the first embodiment. Respective one ends the switches SW2_0 to SW2_8 are supplied with the voltages V0 to V8 from the voltage dividing circuit 11. The respective other ends of the switches SW2_0, SW2_2, SW2_4, SW2_6, and SW2_8 are connected to the output node of the voltage Va. The respective other ends of the switch SW2_1, SW2_3, SW2_5, and SW2_7 are connected to the output node of the voltage Vb.

The high-order bit decoder DECH is supplied with the low-voltage-side power supply voltage VL, as in the first embodiment. The high-order bit decoder DECH decodes the high-order bits D[5:3] and controls turning on/off of each of the switches SW2_0 to SW2_8 according to the decoding result.

Returning to FIG. 5, the configuration of the digital-to-analog converter 200 will further be described. The bit dividing unit 82 receives the 6-bit input digital data D[5:0]. The bit dividing unit 82 divides the input digital data D[5:0] into the three high-order bits D[5:3] and the three low-order bits D[2:0]. The high-order bits D[5:3] are directly output to the selection circuit 22.

The bit dividing unit 82 decodes the high-order bits D[5:3] and outputs the low-order bits D[2:0] directly or in an inverted state to the digital level shift circuit 5 depending on the decoded value. When the decoded value of the high-order bits D[5:3] is an even number, for example, the bit dividing unit 82 directly outputs the low-order bits D[2:0]. In this example, assume that the even number includes 0. On the other hand, when the decoded value of the high-order bits D[5:3] is an odd number, the bit dividing unit 82 inverts the low-order bits D[2:0] and outputs the inverted low-order bits D[2:0]. FIG. 5 illustrates the low-order bits output from the bit dividing unit 82 as the low-order bits D[2:0]_2. The digital level shift circuit 5 outputs high-potential low-order bits D[2:0]_2h which are obtained by shifting the level of the low-order bits D[2:0]_2. The other components of the digital-to-analog converter 200 are the same as those of the digital-to-analog converter 100, so the description thereof is omitted.

Subsequently, the operation of the digital-to-analog converter 200 will be described. The following description will be made assuming that the low-voltage-side power supply voltage VL is 1.0 V; the high-voltage-side power supply voltage VH is 3.0 V; and the high-voltage-side reference voltage Vrh is 1.5 V which is a half of the high-voltage-side power supply voltage, as in the first embodiment.

In the selection circuit 22, the high-order bit decoder DECH decodes the high-order bits D[5:3]. The high-order bit decoder DECH turns on switches SW2_k (k is an integer from 0 to 7) and SW2_(k+1) according to the decoding result. When the decoded value of the high-order bits D[5:3] is “1”, for example, the switches SW2_1 and SW2_2 turn on.

If the switches SW2_k and SW2_(k+1) turn on when k is an even number (the even number includes 0), the voltage Vk is output as the voltage Va and the voltage V (k+1) is output as the voltage Vb. Accordingly, the voltage Va is lower than the voltage Vb.

If the switches SW2_k and SW2_(k+1) turn on when k is an odd number, the voltage Vk is output as the voltage Vb and the voltage V (k+1) is output as the voltage Va. Accordingly, the voltage Va is higher than the voltage Vb.

In short, the selection circuit 22 outputs two adjacent voltages, as the voltages Va and Vb, among the voltages V0 to V8 depending on the decoded value of the high-order bits D[5:3]. In this case, however, the magnitude relation between the voltages Va and Vb is reversed between the case where the decoded value of the high-order bits D[5:3] is an even number and the case where the decoded value of the high-order bits D[5:3] is an odd number.

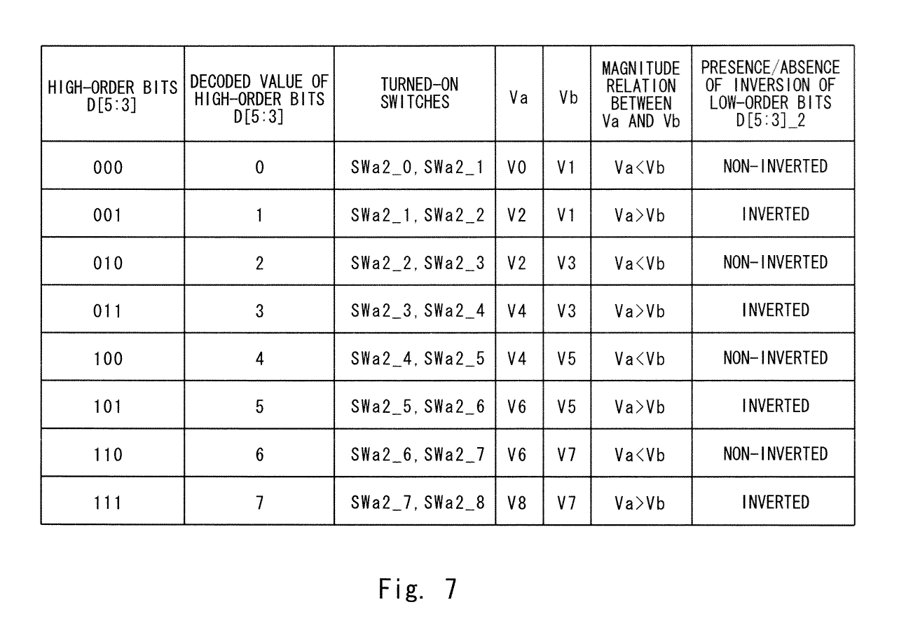

FIG. 7 is an operation chart showing operations in accordance with the high-order bits D[5:3] of the selection circuit 22 and the bit dividing unit 82 according to the second embodiment. The analog level shift circuit 41 outputs the voltages Vah and Vbh based on the voltages Va and Vb. That is, the magnitude relation between the voltages Vah and Vbh is reversed between the case where the decoded value of the high-order bits D[5:3] is an even number and the case where the decoded value of the high-order bits D[5:3] is an odd number. The other operations of the analog level shift circuit 41 are similar to those of the first embodiment, so the description thereof is omitted.

The low-order digital-to-analog converter 6 outputs the output voltage Vnh obtained by dividing a difference voltage between the voltage Vah and the voltage Vbh. In the low-order digital-to-analog converter 6, any of the high-voltage transistor switches SWh0 to SWh7 turns on depending on the decoded value of the high-voltage low-order bits D[2:0]_2h.

When the decoded value of the high-order bits D[5:3] is an even number (the even number includes 0), i.e., when a lowest-order bit D[3] is “0”, the bit dividing unit 82 directly outputs the low-order bits D[2:0]. In this case, the low-order digital-to-analog converter 6 operates in the same manner as in the first embodiment.

On the other hand, when the decoded value of the high-order bits D[5:3] is an odd number, i.e., when the lowest-order bit D[3] is “1”, the bit dividing unit 82 inverts the low-order bits D[2:0] and outputs the inverted low-order bits D[2:0]. Accordingly, when the decoded value of the low-order bits D[2:0] is “k”, the decoded value of the high-voltage low-order bits D[2:0]_2h is expressed as (7−k). As a result, a high-voltage transistor switch SWh (7−k) turns on. However, as compared with the case where the decoded value of the high-order bits D[5:3] is an even number (the even number includes 0), the magnitude relation between the voltages Vah and Vbh is reversed. Therefore, the reversal of the magnitude relation between the voltages Vah and Vbh is cancelled by inversion of the low-order bits D[2:0], so that the low-order digital-to-analog converter 6 according to the second embodiment can output the output voltage Vnh similar to that of the first embodiment.

As described above, the low-order digital-to-analog converter 6 according to the second embodiment can generate the appropriate output voltage Vnh according to the low-order bits D[2:0], like the low-order digital-to-analog converter 6 according to the first embodiment. The other operations of the digital-to-analog converter 200 are similar to those of the digital-to-analog converter 100, so the description thereof is omitted.

The number of switches of the selection circuit 22 according to the second embodiment can be reduced to a half of the number of switches of the selection circuit 21. Consequently, according to this configuration, it is possible to provide a digital-to-analog converter capable of providing the same operations and effects as those of the digital-to-analog converter 100, and achieving further area saving.

### Third Embodiment

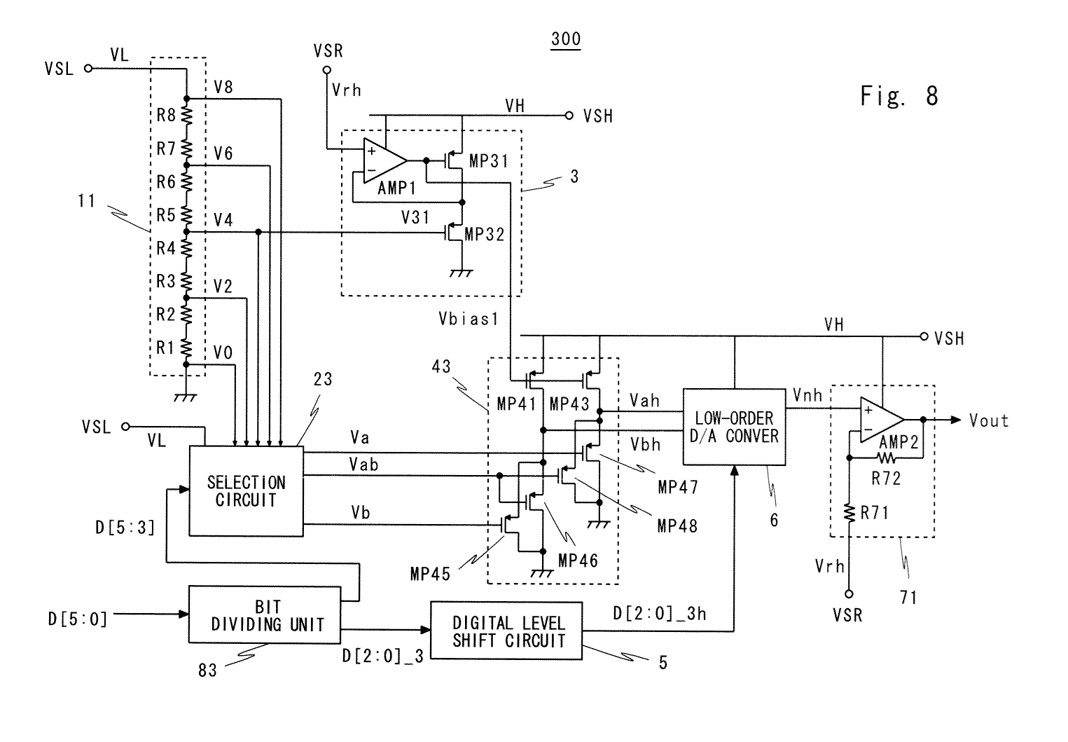

Next, a digital-to-analog converter 300 according to a third embodiment of the present invention will be described. FIG. 8 is a circuit diagram showing the configuration of the digital-to-analog converter 300 according to the third embodiment. The digital-to-analog converter 300 has a configuration in which the selection circuit 21, the analog level shift circuit 41, and the bit dividing unit 81 of the digital-to-analog converter 100 are respectively replaced by a selection circuit 23, an analog level shift circuit 43, and a bit dividing unit 83.

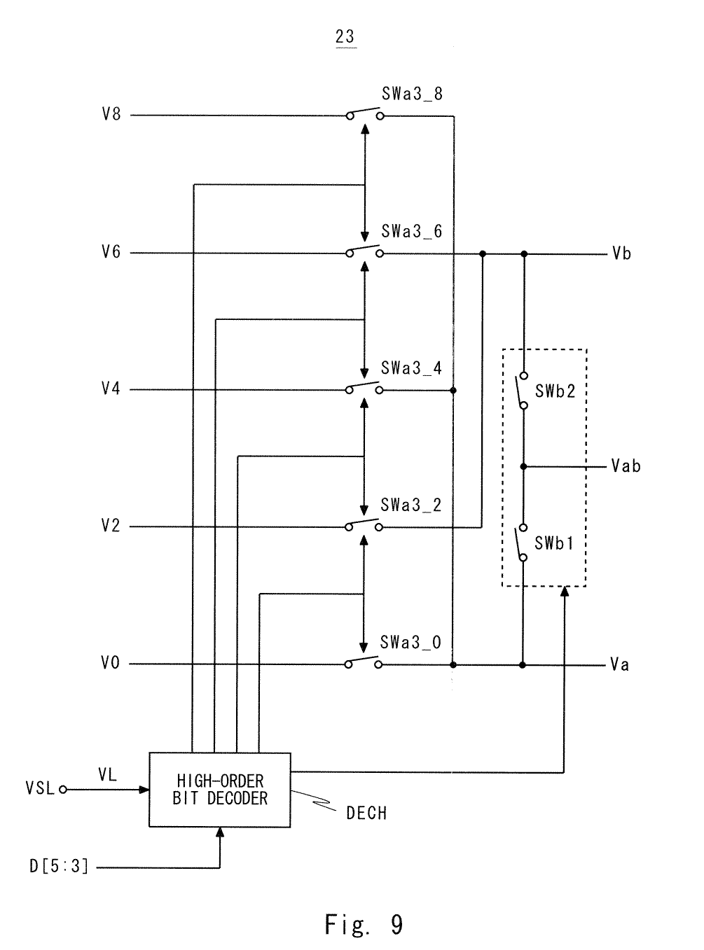

The selection circuit 23 will be described. FIG. 9 is a circuit diagram showing the configuration of the selection circuit 23. The selection circuit 23 includes switches SWa3_0, SWa3_2, SWa3_4, SWa3_6, SWa3_8, SWb1, and SWb2, and the high-order bit decoder DECH. The switches SWa3_0, SWa3_2, SWa3_4, SWa3_6, SWa3_8, SWb1, and SWb2 are each composed of a low-breakdown-voltage transistor, as in the selection circuit 21 according to the first embodiment. Respective one ends the switches SWa3_0, SWa3_2, SWa3_4, SWa3_6, and SWa3_8 are supplied with the voltages V0, V2, V4, V6, and V8 from the voltage dividing circuit 11. The respective other ends of the switches SWa3_0, SWa3_4, and SWa3_8 are connected to the output node of the voltage Va. The respective other ends of the switches SWa3_2 and SWa3_6 are connected to the output node of the voltage Vb. The switch SWb1 is connected between the output node of the voltage Va and an output node of a voltage Vab. The switch SWb2 is connected between the output node of the voltage Vb and the output node of the voltage Vab.

The high-order bit decoder DECH is supplied with the low-voltage-side power supply voltage VL, as in the first embodiment. The high-order bit decoder DECH decodes the high-order bits D[5:3] and controls turning on/off of each of the switches SWa3_0, SWa3_2, SWa3_4, SWa3_6, SWa3_8, SWb1, and SWb2 according to the decoding result.

Returning to FIG. 8, the configuration of the digital-to-analog converter 300 will further be described. The analog level shift circuit 43 includes the Pch transistors MP41 and MP43 and Pch transistors MP45 to M48. The Pch transistors MP45 to MP48 have a channel width which is half the channel width of the Pch transistor MP32, and have the same channel length. The sources of the Pch transistors MP45 and 46 are each connected to the drain of the Pch transistor MP41. The drains of the Pch transistors MP45 and 46 are each connected to the ground GND. The sources of the Pch transistors MP47 and 48 are each connected to the drain of the Pch transistor MP43. The drains of the Pch transistors MP47 and 48 are each connected to the ground GND. The gate of the Pch transistor MP45 is supplied with the voltage Vb. The gate of the Pch transistor MP47 is supplied with the voltage Va. The gates of the Pch transistors MP46 and MP48 are each supplied with the voltage Vab. The other components of the analog level shift circuit 43 are similar to those of the analog level shift circuit 41, so the description thereof is omitted.

The bit dividing unit 83 decodes the high-order bits D[5:3] and outputs the low-order bits D[2:0] directly or in an inverted state to the digital level shift circuit 5 depending on the decoded value. FIG. 8 illustrates the low-order bits, which are output from the bit dividing unit 83, as low-order bits D[2:0]_3. The digital level shift circuit 5 outputs high-potential low-order bits D[2:0]_3h which are obtained by shifting the level of the low-order bits D[2:0]_3. The other components of the digital-to-analog converter 300 are similar to those of the digital-to-analog converter 100, so the description thereof is omitted.

Subsequently, the operation of the digital-to-analog converter 300 will be described. The following description will be made assuming that the low-voltage-side power supply voltage V1, is 1.0 V; the high-voltage-side power supply voltage VH is 3.0 V; and the high-voltage-side reference voltage Vrh is 1.5 V which is a half of the high-voltage-side power supply voltage VH, as in the first embodiment.

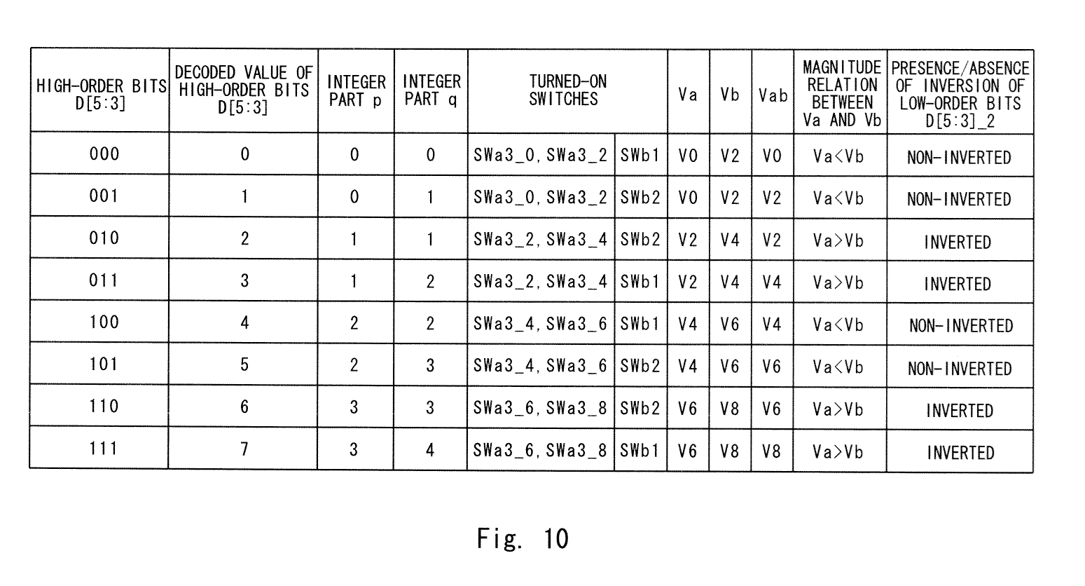

The bit dividing unit 83 decodes the high-order bits D[5:3] and outputs the low-order bits D[2:0] directly or in an inverted state to the digital level shift circuit 5 depending on the decoded value. FIG. 10 is an operation chart showing operations in accordance with the high-order bits D[5:3] of the selection circuit 23 and the bit dividing unit 83 according to the third embodiment. When the decoded value of the high-order bits D[5:3] are 0, 1, 5, or 6, the bit dividing unit 83 directly outputs the low-order bits D[2:0]. On the other hand, when the decoded value of the high-order bits D[5:3] is 2, 3, 6, or 7, the bit dividing unit 82 inverts the low-order bits D[2:0] and outputs the inverted low-order bits D[2:0]. In short, the bit dividing unit 83 inverts the low-order bits D[2:0] depending on the value of a second-lowest-order bit D[4] of the high-order bits D[5:3].

In the selection circuit 23, the high-order bit decoder DECH decodes the high-order bits D[5:3]. Then, the high-order bit decoder DECH turns on only one of the switches SWa3_0, SWa3_2, SWa3_4, SWa3_6, and SWa3_8 according to the decoding result.

Assuming that the integer part of the quotient is “p” (p is an integer from 0 to 3) when the decoded value k (k is an integer from 0 to 7) of the high-order bits D[5:3] is divided by “2”, a switch SW3_(2p) and a switch {2(p+1)} turn on. When the value of the second-lowest-order bit D[4] of the high-order bits D[5:3], i.e., when the value of the integer part p is an even number (the even number includes 0), the voltage Va is lower than the voltage Vb. When the value of the second-lowest-order bit D[4] of the high-order bits D[5:3] is “1”, i.e., when the value of the integer part p is an odd number, the voltage Va is higher than the voltage Vb. That is, the selection circuit 23 outputs, as the voltages Va and Vb, two adjacent voltages among the voltages V0, V2, V4, V6, and V8 depending on the decoded value of the high-order bits D[5:3]. In this case, however, the magnitude relation between the voltages Va and Vb is reversed between the case where the integer part p is an even number and the case where the integer part is an odd number.

Assume that the integer part of the quotient obtained when the value obtained by adding “1” to the decoded value k of the high-order bits D[5:3] is divided by “2” is represented by q. When q is an even number (the even number includes 0), i.e., when the value of the second-lowest-order bit D[4] of the high-order bits D[5:3] is equal to the value of the lowest-order bit D[3], the switch SWb1 turns on. When q is an odd number, i.e., when the value of the second-lowest-order bit D[4] of the high-order bits D[5:3] is different from the value of the lowest-order bit D[3], the switch SWb2 turns on. Accordingly, as shown in FIG. 10, the voltages Va, Vb, and Vab change depending on the high-order bits D[5:3].

The analog level shift circuit 43 outputs the voltages Vah and Vbh based on the voltages Va, Vb, and Vab. For example, when the voltage Va and the voltage Vab are equal to the voltage V0 and the voltage Vb is equal to the voltage V2, the voltages Vah and Vbh are expressed by the following equations (2) and (3), respectively.

Vah=V0+1.0[V] (2)

Vbh=(V0+V2)/2+1.0[V]=V1+1.0[V] (3)

For example, when the voltage Va is equal to the voltage V0 and the voltages Vb and Vab are equal to the voltage V2, the voltages Vah and Vbh are expressed by the following equations (4) and (5), respectively.

Vah=(V0+V2)/2+1.0[V]=V1+1.0[V] (4)

Vbh=V2+1.0[V] (5)

In this case, in the analog level shift circuit 43, the voltage V1, which is an intermediate voltage between the voltage V0 and the voltage V2, is output as the voltage Vah or Vbh. In other words, cooperation between the selection circuit 23 and the analog level shift circuit 43 enables supply of two adjacent voltages among the voltages V0 to V8 to the low-order digital-to-analog converter 6 depending on the high-order bits D[5:3].

The low-order digital-to-analog converter 6 outputs the output voltage Vnh obtained by dividing the difference voltage between the voltage Vah and the voltage Vbh. In the low-order digital-to-analog converter 6, any of the high-voltage transistor switches SWh0 to SWh7 turns on depending on the decoded value of high-voltage low-order bits D[2:0]H.

If the integer part p of the quotient obtained when the decoded value of the high-order bits D[5:3] is divided by “2” is an even number (the even number includes 0), the bit dividing unit 82 directly outputs the low-order bits D[2:0]. In this case, the low-order digital-to-analog converter 6 performs operation similar to that of the first embodiment.

On the other hand, if the integer part p of the quotient obtained when the decoded value of the high-order bits D[5:3] is divided by “2” is an odd number, the bit dividing unit 82 inverts the low-order bits D[2:0] and outputs the inverted low-order bits D[2:0]. In this case, as in the second embodiment, the reversal of the magnitude relation between the voltages Vah and Vbh is cancelled by inversion of the low-order bits D[2:0]. Accordingly, the low-order digital-to-analog converter 6 according to the third embodiment can generate the appropriate output voltage Vnh depending on the low-order bits D[2:0], as with the low-order digital-to-analog converter 6 according to the first and second embodiments. The other operations of the digital-to-analog converter 300 are similar to those of the digital-to-analog converter 100, so the description thereof is omitted.

In the selection circuit 23 according to the third embodiment, the number of switches can be reduced as compared with the selection circuits 21 and 22. Therefore, according to this configuration, it is possible to provide a digital-to-analog converter capable of providing the same operations and effects as those of the digital-to-analog converters 100 and 200 and achieving further area saving.

Moreover, in the digital-to-analog converter 300, the number of voltages output from the voltage dividing circuit 11 can be reduced, and thus the number of resistors connected in series can also be reduced. This is advantageous in terms of area saving in the digital-to-analog converter.

### Fourth Embodiment

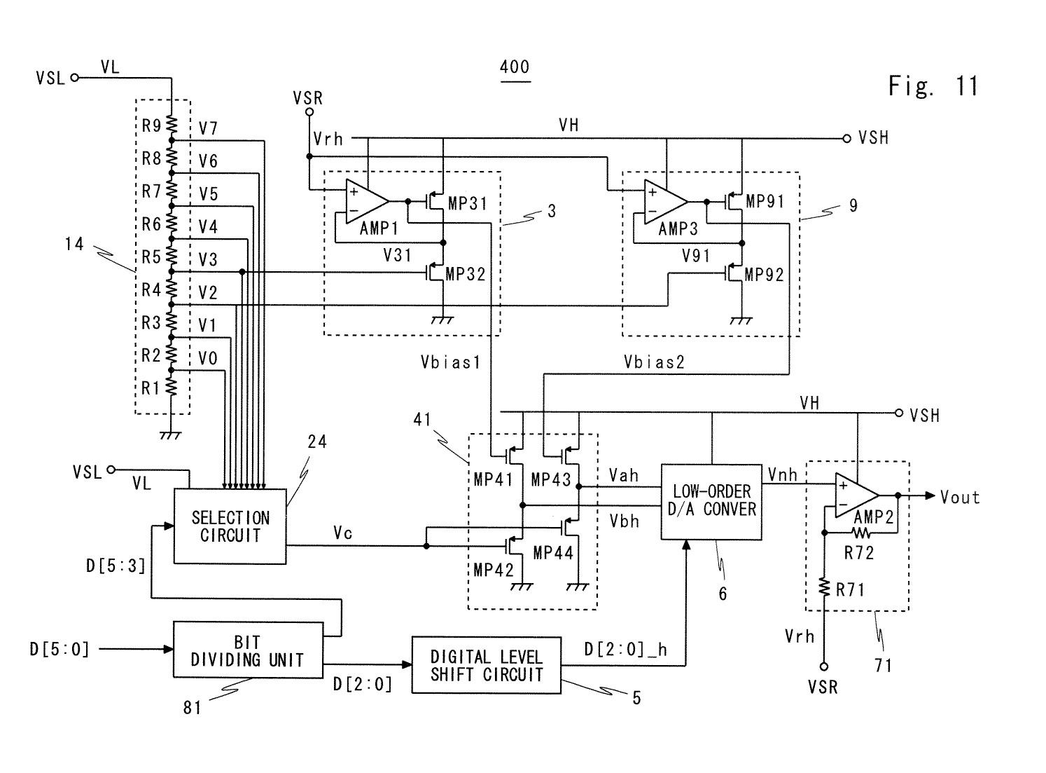

Next, a digital-to-analog converter 400 according to a fourth embodiment of the present invention will be described. The digital-to-analog converter 400 is a 6-bit digital-to-analog converter. FIG. 11 is a circuit diagram showing the configuration of the digital-to-analog converter 400 according to the fourth embodiment. The digital-to-analog converter 400 has a configuration in which the voltage dividing circuit 11 and the selection circuit 21 of the digital-to-analog converter 100 are respectively replaced by a voltage dividing circuit 14 and a selection circuit 24 and a bias generation circuit 9 is added.

In the voltage dividing circuit 14, a resistor R9 is added between the resistor R8 and the high-voltage-side power supply VSH. The voltage dividing circuit 14 outputs the voltages V0 to V7 from the low-voltage-side ends of the resistors R2 to R9 to the selection circuit 24. Accordingly, the voltages V0 to V7 do not include the low-voltage-side power supply voltage VL and the ground voltage GND. Note that in the fourth embodiment, assume that the value of the voltage V4 is 0.5 V and the voltage pitch of the voltages V0 to V7 is 0.5 V. The other components of the voltage dividing circuit 14 are similar to those of the voltage dividing circuit 11, so the description thereof is omitted.

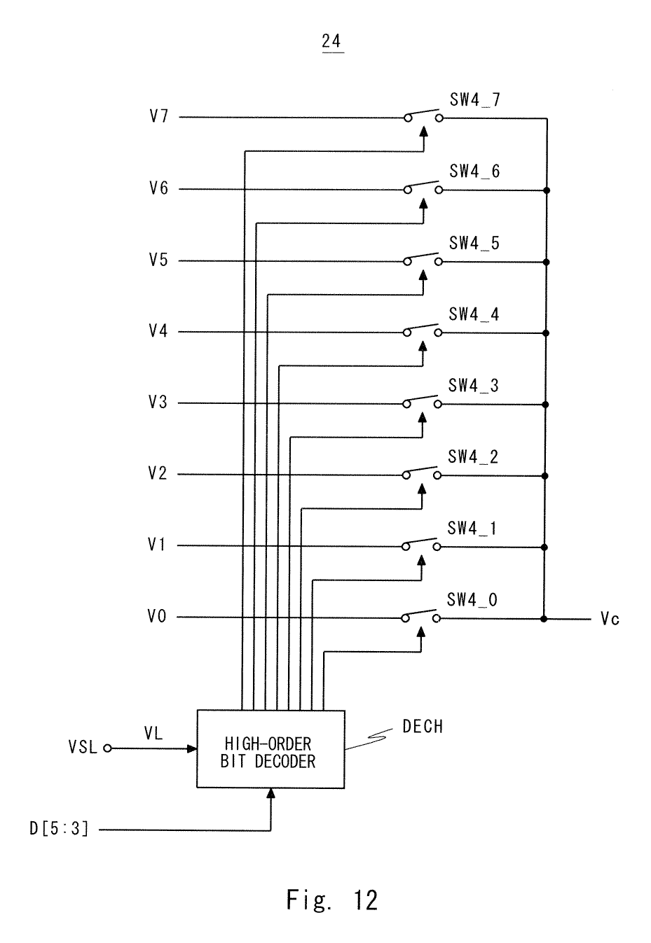

The configuration of the selection circuit 24 will now be described. FIG. 12 is a circuit diagram showing the configuration of the selection circuit 24. The selection circuit 24 includes switches SW4_0 to SW_7 and the high-order bit decoder DECH. The switches SW4_0 to SW_7 are each composed of a low-breakdown-voltage transistor. Respective one ends of the switches SW4_0 to SW_7 are supplied with the voltages V0 to V8 from the voltage dividing circuit 14, and the respective other ends of the switches SW4_0 to SW_7 are connected to an output node of a voltage Vc. The high-order bit decoder DECH is supplied with the low-voltage-side power supply voltage VL. The high-order bit decoder DECH decodes the high-order bits D[5:3] and controls turning on/off of the switches SW4_0 to SW_7 according to the decoding result.

Returning to FIG. 11, the configuration of the digital-to-analog converter 400 will further be described. The bias generation circuit 9 includes an amplifier AMP3 and Pch transistors MP91 and MP92. The bias generation circuit 9 has a configuration substantially the same as that of the bias generation circuit 3. Specifically, the configurations of the amplifier AMP3 and the Pch transistors MP91 and MP92 and the connection relation therebetween are the same as those of the amplifier AMP1 and the Pch transistors MP31 and MP32 of the bias generation circuit 3, except that the voltage V3 is supplied to the gate of the Pch transistor MP92.

The gate of the Pch transistor MP41 of the analog level shift circuit 41 is supplied with the bias voltage Vbias1 from the bias generation circuit 3. The gate of the Pch transistor MP43 is supplied with a bias voltage Vbias2 from the bias generation circuit 9. The gates of the Pch transistors MP42 and MP44 are supplied with the voltage Vc from the selection circuit 24. The other components of the analog level shift circuit 41 are similar to those of the analog level shift circuit 41 according to the first embodiment. The other components of the digital-to-analog converter 400 are also similar to those of the digital-to-analog converter 100, so the description thereof is omitted.

Subsequently, the operation of the digital-to-analog converter 400 will be described. The following description will be made assuming that the low-voltage-side power supply voltage VL is 1.0 V; the high-voltage-side power supply voltage VH is 3.0 V; and the high-voltage-side reference voltage Vrh is 1.5 V which is a half of the high-voltage-side power supply voltage VH, as in the first embodiment.

As described above, the bias generation circuit 3 outputs the bias voltage Vbias1 to cause a bias current for generating the output voltage (voltage V31), which is obtained by shifting the level of the input voltage (voltage V4) by 1.0 V, to flow.

In the bias generation circuit 9, the voltage V3 (0.45 V) is supplied to the gate of the Pch transistor MP92. Since the high-voltage-side reference voltage Vrh is 1.5 V, when the voltage V3 (0.45 V) is supplied to the gate of the Pch transistor MP92 in the bias generation circuit 9, a feedback is applied so as to maintain a voltage V91 at a node between the Pch transistor MP91 and the Pch transistor MP92 at 1.5 V. That is, the bias generation circuit 9 outputs the bias voltage Vbias2 to cause a bias current for generating the output voltage (voltage V91) obtained by shifting the level of the input voltage (voltage V3) by 0.95 V.

The high-order bit decoder DECH of the selection circuit 24 decodes the high-order bits D[5:3]. Further, the high-order bit decoder DECH turns on only a switch SW4_k depending on the decoded value k (k is an integer from 0 to 7), and outputs the voltage Vk as the voltage Vc.

The gates of the Pch transistors MP41 and MP43 of the analog level shift circuit 41 are respectively supplied with different bias voltages Vbias1 and Vbias2. Accordingly, the level of the voltage Vc is shifted by 1.0 V and 0.95 V. The voltage whose level is shifted by 1.0 V is output as the voltage Vbh, and the voltage whose level is shifted by 0.95 V is output as the voltage Vah. Therefore, the analog level shift circuit 41 can output a pair of voltages Vah and Vbh from a single voltage Vc. Since the voltage Vc is changed in eight levels by the selection circuit 24, the analog level shift circuit 41 can output eight combinations of the voltages Vah and Vbh, as in the first embodiment. The other operations of the digital-to-analog converter 400 are similar to those of the digital-to-analog converter 100, so the description thereof is omitted.

In the selection circuit 24 according to the fourth embodiment, the number of switches can be reduced as compared with the selection circuit 21. Therefore, according to this configuration, it is possible to provide a digital-to-analog converter capable of providing the same operations and effects as those of the digital-to-analog converter 100 and achieving further area saving.

Though the bias generation circuit 9 is added in this embodiment, the bias generation circuit 9 can be formed with a simple circuit configuration. For this reason, an increase in circuit area due to addition of the bias generation circuit 9 is less than a decrease in circuit area due to reduction in the number of switches of the selection circuit 24. Consequently, area saving in the digital-to-analog converter can be achieved even when the bias generation circuit 9 is added.

### Fifth Embodiment

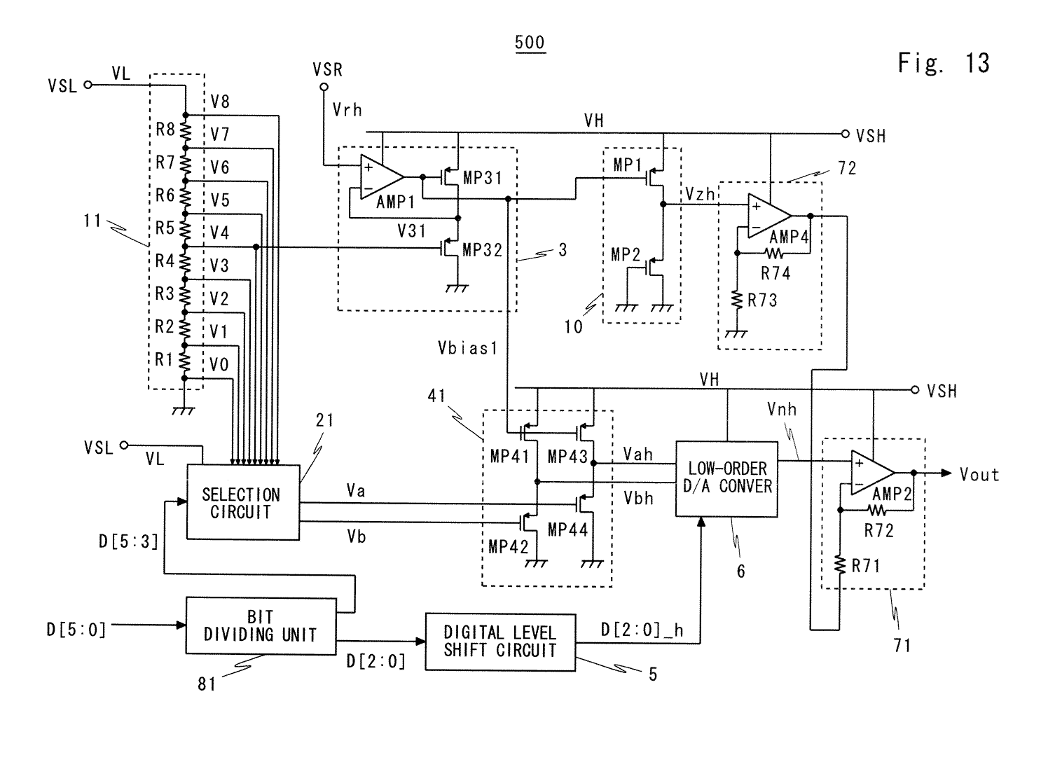

Next, a digital-to-analog converter 500 according to a fifth embodiment of the present invention will be described. FIG. 13 is a circuit diagram showing the configuration of the digital-to-analog converter 500 according to the fifth embodiment. The digital-to-analog converter 500 has a configuration in which an analog level shift circuit 10 and an amplifier circuit 72 are added to the digital-to-analog converter 100.

The analog level shift circuit 10 includes Pch transistors MP1 and MP2. The Pch transistors MP1 and MP2 are cascode-connected between the high-voltage-side power supply VSH and the ground GND. Specifically, the source of the Pch transistor MP1 is connected to the high-voltage-side power supply VSH, and the drain of the Pch transistor MP1 is connected to the source of the Pch transistor MP2. The drain of the Pch transistor MP2 is connected to the ground GND. The gate of the Pch transistor MP1 is connected to the output terminal of the amplifier AMP1 of the bias generation circuit 3. The gate of the Pch transistor MP2 is connected to the ground GND. An output voltage Vzh is output from a node between the Pch transistors MP1 and MP2.

The amplifier circuit 72 is supplied with power from the high-voltage-side power supply VSH, and outputs a reference voltage Vref which is obtained by amplifying the output voltage Vzh. The amplifier circuit 72 includes an amplifier AMP4 and resistors R73 and R74. The amplifier AMP4 is supplied with power from the high-voltage-side power supply VSH. A non-inverting input terminal of the amplifier AMP4 is supplied with the output voltage Vzh from the analog level shift circuit 10. An inverting input terminal of the amplifier AMP4 is connected to the ground GND through the resistor R73. The inverting input terminal of the amplifier AMP4 is connected to an output terminal of the amplifier AMP4 through the resistor R74. The output terminal of the amplifier AMP4 supplies the reference voltage Vref to the resistor R71 of the output amplifier circuit 71.

In short, the amplifier circuit 72 is configured as a positive-phase amplifier. In the amplifier circuit 72, the resistance value of the resistor R73 is represented by NR, and the resistance value of the resistor R74 is represented by R. Accordingly, the amplification factor Av of the amplifier circuit 72 can be expressed as the following equation (6).

Av=1+1/N (6)

Subsequently, the operation of the digital-to-analog converter 500 will be described. The following description will be made assuming that the low-voltage-side power supply voltage VL is 0.8 V; the high-voltage-side power supply voltage VH is 3.0 V; and the high-voltage-side reference voltage Vrh is 1.5 V which is a half of the high-voltage-side power supply voltage VH. Since the low-voltage-side power supply voltage VL is 0.8 V, the voltage V4 is 0.4 V.

In the bias generation circuit 3, the voltage V4 (0.4 V) is supplied to the gate of the Pch transistor MP32. Since the high-voltage-side reference voltage Vrh is 1.5 V, when the voltage V4 (0.4 V) is supplied to the gate of the Pch transistor MP32 in the bias generation circuit 3, a feedback is applied so as to maintain the voltage at the node between the Pch transistor MP31 and the Pch transistor MP32, at 1.5 V. Accordingly, the output voltage Vzh is 1.1 V.

When the output amplifier circuit 71 has a triple amplification factor, the value N of the resistance value NR of the resistor R72 is “2”. In this case, the amplification factor of the amplifier circuit 72 is expressed as 3/2 by the equation (6). Accordingly, when the output voltage Vzh is 1.1 V, the reference voltage Vref is 1.65 V.

When the decoded value of the high-order bits is “0”, i.e., when the selection circuit 21 outputs the voltages V0 and V1 as the voltages Va and Vb, respectively, the voltages Vah and Vbh can be expressed by the following equations (7) and (8), respectively.

Vah=V0+1.1[V] (7)

Vbh=V1+1.1[V] (8)

Here, when the decoded value of the low-order bits D[2:0] is “0”, the output voltage Vnh can be expressed by the following equation (9).

Vnh=V0+1.1[V] (9)

The voltage V0 is a ground voltage, i.e., 0 V. Accordingly, the output voltage Vnh obtained in this case is 1.1 V.

The output amplifier circuit 71 amplifies the difference voltage (−0.55 V) between the reference voltage Vref (1.65 V) and the output voltage Vnh (1.1 V) to be tripled. Accordingly, the output voltage Vout at this time can be expressed by the following equation (10).

$$\begin{matrix}Vout = Vref + Av 71 ( Vnh - Vref ) \\ = 1.65 + 3 \times ( - 0.55 ) \\ = 0 [ V ]\end{matrix} \qquad ( 10 )$$

That is, adjustment of the resistance value of each resistor of the output amplifier circuit 71 and the amplifier circuit 72 enables adjustment of the output voltage Vout to 0 V when the value of the input digital data is “0”. This enables adjustment of the dynamic range of the output voltage Vout based on 0 V.

The present invention is not limited to the above embodiments, but may be modified as appropriate without departing from the gist of the present invention. For example, the amplifier circuit 72 according to the fifth embodiment may be added to each of the digital-to-analog converters according to the first to fourth embodiments. This allows the digital-to-analog converters according to the first to fourth embodiments to adjust the dynamic range of the output voltage Vout based on 0 V.

The first to fifth embodiments have described the 6-bit input digital data by way of example, but the number of bits of input digital data is not limited to this. In other words, the digital-to-analog converters according to the first to fifth embodiments can be configured to be compatible with input digital data of any other arbitrary number of bits by changing the number of resistors and switches of the voltage dividing circuit, the selection circuit, and the low-order digital-to-analog converter depending on the number of bits of the input digital data. While the 6-bit input digital data is divided into two 3-bit data items in the first to fifth embodiments described above, the division ratio of the input digital data is not limited to this example. That is, the input digital data can be divided into two groups: m (m is an integer equal to or greater than 2) high-order bits and n (n is an integer equal to or greater than 2) low-order bits.

The voltage dividing circuit is not limited to the configuration having resistors connected in series as in the first to fifth embodiments, but may have any configuration as long as the voltage dividing circuit can output a plurality of voltages that change stepwise.

While Pch transistors are used as switches in the first to fifth embodiments described above, the Pch transistors may be replaced by Nch transistors as needed, as long as the same functions can be achieved.

The first to fifth embodiments can be combined as desirable by one of ordinary skill in the art.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A digital-to-analog converter comprising:
a selection circuit that is supplied with a low-voltage-side power supply voltage from a low-voltage-side power supply, and outputs a voltage that changes in 2^{m} (m is an integer equal to or greater than 2) levels depending on m-bit digital data to be input;
a level shift circuit that generates a voltage by shifting a level of the voltage output from the selection circuit by a predetermined value; and
an n (n is an integer equal to or greater than 2)-bit digital-to-analog converter that is supplied with a high-voltage-side power supply voltage from a high-voltage-side power supply, and outputs an output voltage that changes in 2^{(m+n)} levels by changing the voltage generated by the level shift circuit in 2ⁿ levels depending on n-bit digital data to be input.

2. The digital-to-analog converter according to claim 1, wherein the selection circuit comprises:
a plurality of low-voltage transistors that operate at a level of the low-voltage-side power supply voltage; and
a first decoder that decodes the m-bit digital data and turns on a transistor selected from the plurality of low-voltage transistors according to a decoding result to allow the transistor to output the voltage to the level shift circuit.

3. The digital-to-analog converter according to claim 2, wherein the n-bit digital-to-analog converter comprises:
a first voltage dividing circuit that generates divided voltages obtained by dividing the voltage generated by the level shift circuit in 2ⁿ levels;
a plurality of high-voltage transistors that are supplied with the divided voltages obtained by dividing the voltage in 2ⁿ levels, and have a breakdown voltage higher than that of the low-voltage transistors that operate at the level of the low-voltage-side power supply voltage; and
a second decoder that decodes the n-bit digital data, and turns on a transistor selected from the plurality of high-voltage transistors according to a decoding result to allow the transistor to output, as the output voltage, one of the divided voltages obtained by dividing the voltage in 2ⁿ levels.

4. The digital-to-analog converter according to claim 3, wherein the second decoder turns on the high-voltage transistor supplied with the divided voltages of higher levels along with an increase in a decoded value of the n-bit digital data.

5. The digital-to-analog converter according to claim 4, further comprising a bit dividing unit that divides (m+n)-bit input digital data into m high-order bits and n low-order bits,
wherein the m-bit digital data corresponds to the high-order bits and the n-bit digital data corresponds to the low-order bits.

6. The digital-to-analog converter according to claim 3, wherein
the selection circuit outputs a first voltage selected from a plurality of voltages, and a second voltage that is higher than the first voltage by one level,
the level shift circuit outputs, as a third voltage, a voltage obtained by shifting a level of the first voltage by a first value, and outputs, as a fourth voltage, a voltage obtained by shifting a level of the second voltage by the first value, and
the first voltage dividing circuit divides a voltage between the third voltage and the fourth voltage in 2ⁿ levels.

7. The digital-to-analog converter according to claim 6, wherein the selection circuit comprises:
2^{m} first low-voltage transistors having one end supplied with lower 2^{m} voltages among (2^{m}+1) voltages of different levels, and having another end connected to an output node of the first voltage; and
2^{m} second low-voltage transistors having one end supplied with higher 2^{m} voltages among the (2^{m}+1) voltages, and having another end connected to an output node of the second voltage, and
the first decoder determines the first voltage by turning on any of the 2^{m} first low-voltage transistors, and determines the second voltage by turning on any of the 2^{m} second low-voltage transistors.

8. The digital-to-analog converter according to claim 6, wherein
the bit dividing unit directly outputs the n-bit digital data to the n-bit digital-to-analog converter when the first voltage is lower than the second voltage, and
the bit dividing unit inverts the n-bit digital data and outputs the inverted n-bit digital data to the n-bit digital-to-analog converter when the first voltage is higher than the second voltage.

9. The digital-to-analog converter according to claim 8, wherein the selection circuit comprises:
(2^{(m-1)}+1) first low-voltage transistors having one end supplied with an odd-numbered voltage counted from a lowest voltage among (2^{m}+1) voltages with voltage values increasing stepwise, and having another end connected to an output node of the first voltage; and
2^{(m-1)} second low-voltage transistors having one end supplied with an even-numbered voltage counted from a highest voltage among the (2^{m}+1) voltages, and having another end connected to an output node of the second voltage, and
the first decoder determines the first voltage by turning on any of the (2^{(m-1)}+1) first low-voltage transistors, and determines the second voltage by turning on any of the 2^{(m-1)} second low-voltage transistors.

10. The digital-to-analog converter according to claim 9, wherein
the bit dividing unit directly outputs the n-bit digital data to the n-bit digital-to-analog converter when a decoded value of the high-order bits is an odd number, and
the bit dividing unit inverts the n-bit digital data and outputs the inverted n-bit digital data to the n-bit digital-to-analog converter when the decoded value of the high-order bits is an even number.

11. The digital-to-analog converter according to claim 5, wherein
the bit dividing unit directly outputs the n-bit digital data to the n-bit digital-to-analog converter when the first voltage is lower than the second voltage, and
the bit dividing unit inverts the n-bit digital data and outputs the inverted n-bit digital data to the n-bit digital-to-analog converter when the first voltage is higher than the second voltage.

12. The digital-to-analog converter according to claim 11, wherein
the selection circuit outputs, as a first voltage, a voltage selected from a plurality of voltages, outputs, as a second voltage, a voltage higher than the first voltage by one level, and output, as a third voltage, a voltage equal to one of the first voltage and the second voltage,
the level shift circuit generates a fourth voltage by shifting a level of an intermediate voltage between the first voltage and the third voltage by a first value, and generates a fifth voltage by shifting a level of an intermediate voltage between the second voltage and the third voltage by the first value, and
the first voltage dividing circuit divides a voltage between the fourth voltage and the fifth voltage in 2ⁿ levels.

13. The digital-to-analog converter according to claim 12, wherein the selection circuit comprises:
(2^{(m-2)}+1) first low-voltage transistors having one end supplied with an odd-numbered voltage counted from a lowest voltage among (2^{(m-1)}+1) voltages with voltage values increasing stepwise, and having another end connected to an output node of the first voltage;
2^{(m-2)} second low-voltage transistors having one end supplied with an even-numbered voltage counted from a highest voltage among the (2^{(m-1)}+1) voltages, and having another end connected to an output node of the second voltage;
a third low-voltage transistor connected between the output node of the first voltage and an output node of a third voltage; and
a fourth low-voltage transistor connected between the output node of the second voltage and the output node of the third voltage,
the first decoder determines the first voltage by turning on any of the 2^{(m-1)}+1) first low-voltage transistors connected to the output node of the first voltage,
the first decoder determines the second voltage by turning on any of the 2^{(m-2)} second low-voltage transistors connected to the output node of the second voltage, and
the first decoder complementarily turns on the third low-voltage transistor and the fourth low-voltage transistor so that one of the first voltage and the second voltage is output as the third voltage.

14. The digital-to-analog converter according to claim 13, wherein
the bit dividing unit directly outputs the n-bit digital data to the n-bit digital-to-analog converter when a second lowest bit of the high-order bits is 1,
the bit dividing unit inverts the n-bit digital data and outputs the inverted n-bit digital data to the n-bit digital-to-analog converter when the second lowest bit of the high-order bits is 0,
the bit dividing unit turns on the third low-voltage transistor when a lowest bit of the high-order bits is equal to the second lowest bit, and
the bit dividing unit turns on the fourth low-voltage transistor when the lowest bit of the high-order bits is different from the second lowest bit.

15. The digital-to-analog converter according to claim 3, wherein
the selection circuit outputs, as a first voltage, a voltage selected from a plurality of voltages,
the level shift circuit generates a second voltage by shifting a level of the first voltage by a first value, and regenerates a third voltage by shifting a level of the first voltage by a second value different from the first value, and
the first voltage dividing circuit divides a voltage between the second voltage and the third voltage in 2ⁿ levels.

16. The digital-to-analog converter according to claim 15, wherein the first value is smaller than the second value.

17. The digital-to-analog converter according to claim 16, wherein
the selection circuit comprises 2^{m} low-voltage transistors having one end supplied with 2^{m} voltages of different levels, and having another end connected to an output node of the third voltage, and
the first decoder determines the first voltage by turning on any of the 2^{m} low-voltage transistors.

18. The digital-to-analog converter according to claim 5, further comprising a digital level shift circuit that is disposed between the bit dividing unit and the n-bit digital-to-analog converter, and outputs, to the n-bit digital-to-analog converter, the n-bit digital data by shifting a level of the n-bit digital data from the bit dividing unit by a predetermined value.

19. The digital-to-analog converter according to claim 1, further comprising an output amplifier circuit that amplifies the output voltage based on a supplied reference voltage.

20. A circuit comprising:
a selector coupled to a first power line to output a first voltage and a second voltage;
a digital-to-analog (D/A) converter coupled to a second power line to output an output voltage based on a first reference voltage and a second reference voltage, the second power line having a higher voltage than that of the first power line; and
a level shifter, wherein
the level shifter comprises:
a first transistor having a source thereof coupled to the second power line, a gate thereof coupled to a bias voltage and a drain thereof coupled to the first reference voltage;
a second transistor having a source thereof coupled to the first reference voltage, a gate thereof coupled to the first voltage and a drain thereof;
a third transistor having a source thereof coupled to the second power line, a gate thereof coupled to the bias voltage and a drain thereof coupled to the second reference voltage; and
a fourth transistor having a source thereof coupled to the second reference voltage, a gate thereof coupled to the second voltage and drain thereof.
